(19) United States
(12) Patent Application Publication
(10) Pub. No.: US 2025/0318103 A1
(43) Pub. Date: Oct. 9, 2025

(54) TRANSISTOR DEVICE AND MEMORY

(71) Applicant: INSTITUTE OF MICROELECTRONICS OF THE CHINESE ACADEMY OF SCIENCES, Beijing (CN)

(72) Inventors: Ling LI, Beijing (CN); Ming LIU, Beijing (CN); Di GENG, Beijing (CN); Xinlv DUAN, Beijing (CN); Congyan LU, Beijing (CN)

(73) Assignee: INSTITUTE OF MICROELECTRONICS OF THE CHINESE ACADEMY OF SCIENCES, Beijing (CN)

(21) Appl. No.: 18/873,201

(22) PCT Filed: Aug. 24, 2022
(86) PCT No.: PCT/CN2022/114595

§ 371 Date: Dec. 9, 2024

(30) Foreign Application Priority Data
Jun. 10, 2022 (CN) 202210657949.3

(51) Int. Cl. H10B 12/00

(52) U.S. Cl. CPC H10B 12/00

(57) ABSTRACT

Disclosed are a transistor device and a memory. The transistor device comprises: a gate; a gate insulating layer, covering the surface of the gate; a semiconductor channel, covering the surface of the gate insulating layer away from the gate; a first source drain, surrounding the side of the gate insulating layer away from the gate and located at a first end of the gate; and a second source drain, arranged on the side of the gate insulating layer away from the gate and located at a second end of the gate. According to the transistor device structure formed in the present disclosure, a semiconductor channel-all-around gate is formed, the area corresponding to the semiconductor channel and the gate is increased, the control capability of the gate with respect to the semiconductor channel is effectively enhanced, and the size of the device can be further reduced.

### CROSS-REFERENCE TO RELATED PATENT APPLICATIONS

This application claims a priority from the Chinese Patent Application No. 202210657949.3, filed with the Chinese Patent Office on Jun. 10, 2022, entitled “TRANSISTOR DEVICE AND MEMORY”, contents of which is incorporated herein by reference in its entirety.

### FIELD OF THE INVENTION

The disclosure relates to the technical field of semiconductor, and in particular to a transistor device and a memory.

### BACKGROUND OF THE INVENTION

At present, an integrated circuit is constantly evolving to finer dimensions, with advanced process being one of the top several nodes in integrated circuit fabrication. While the size of a transistor continues to shrink, a planar transistor structure gradually shows defects such as a relatively high leakage current. Therefore, in order to meet better gate control performance and avoid the leakage current, it is a current mainstream development direction to make a three-dimensional structure of a Fin Field Effect Transistor (FinFET). However, it is difficult for the current process to further reduce a channel area on this structure, and it is difficult to further shrink the entire device structure.

Therefore, it is an urgent problem to be solved how to ensure a good gate control ability of the device and further reduce the size of the device.

### SUMMARY OF THE INVENTION

In view of the above problems, the present disclosure presents a transistor device and a memory, which enhance the control ability of a gate on a semiconductor channel, and facilitate further miniaturization of the size of a device.

In a first aspect of the present disclosure, there is provided a transistor device comprising: a gate; a gate insulating layer arranged around a side of the gate; a semiconductor channel arranged around a side of the gate insulating layer away from the gate; a first source drain arranged around the side of the gate insulating layer away from the gate and located at a first end of the gate; and a second source drain arranged on the side of the gate insulating layer away from the gate and located at a second end of the gate.

In a second aspect of the present disclosure, there is provided a memory comprising the transistor device as described above.

According to one or more embodiments of the present disclosure, there is provided a transistor device and a memory, wherein in the transistor device, a gate insulating layer is arranged around a side of a gate; a semiconductor channel is arranged around a side of the gate insulating layer away from the gate; a first source drain is arranged around the side of the gate insulating layer away from the gate and is located at a first end of the gate; and a second source drain is arranged on the side of the gate insulating layer away from the gate and is located at a second end of the gate. The resulting transistor device structure forms a semiconductor channel-all-around gate, which increases the area of the semiconductor channel corresponding to the gate, effectively enhances the control capability of the gate with respect to the semiconductor channel, and facilitates further miniaturization of the size of the device. At the same time, the semiconductor channel can have a relatively large area, increasing the number of carriers and improving the performance.

The foregoing description is merely a summary of the technical solutions of the present disclosure. In order that the technical means of the present disclosure can be more clearly understood to be practiced in light of the description, and in order that the above and other objects, features and advantages of the present disclosure can be more clearly understood, the following sets forth specific embodiments of the present disclosure.

### BRIEF DESCRIPTION OF THE DRAWINGS

In order to more clearly illustrate technical solutions in embodiments of the present disclosure, the accompanying drawings used in the description of the embodiments will now be briefly described. It will be apparent that the drawings in the following description are some embodiments of the present disclosure and that other drawings can be derived from these drawings without inventive step for a person of ordinary skill in the art.

FIGS. 1, 2, 3, and 7 are schematic diagrams of different structures of a transistor device according to one or more embodiments of the present disclosure, respectively;

FIG. 4 is a schematic diagram of the gate position structure of a transistor device according to one or more embodiments of the present disclosure;

FIGS. 5 and 6 are schematic diagrams of electric field distribution at a second end of a gate of a different transistor device according to one or more embodiments of the present disclosure, respectively;

FIG. 8 is a schematic diagram of the semiconductor channel of a transistor device according to one or more embodiments of the present disclosure; and

FIG. 9 is a schematic diagram of the structure of a 2T0C device structure composed of a transistor device according to one or more embodiments of the present disclosure.

### DETAILED DESCRIPTION OF THE INVENTION

Embodiments of the present disclosure will be described with reference to the accompanying drawings. It should be understood, however, that these descriptions are merely exemplary and are not intended to limit the scope of the present disclosure. Furthermore, in the following descriptions, descriptions of well-known structures and techniques are omitted to avoid unnecessarily confusing the concepts of the present disclosure.

Various schematic drawings of structures according to embodiments of the present disclosure are shown in the accompanying drawings. These drawings are not to scale, in which certain details have been enlarged and may have been omitted for purposes of clarity. The shapes of the various regions and layers as well as the relative sizes and positional relationships among them shown in the drawings are only exemplary and can be deviated from in practice due to manufacturing tolerances or technical limitations, and the person skilled in the art may additionally design regions/layers with different shapes, sizes, and relative positions according to actual needs.

In the context of the present disclosure, when a layer/element is referred to as being disposed “on” another layer/element, the layer/element can be disposed directly on that other layer/element, or there can be an intervening layer/element between them. Alternatively, if a layer/element is disposed “on” another layer/element in one orientation, the layer/element can be disposed “under” the other layer/element when the orientation is reversed.

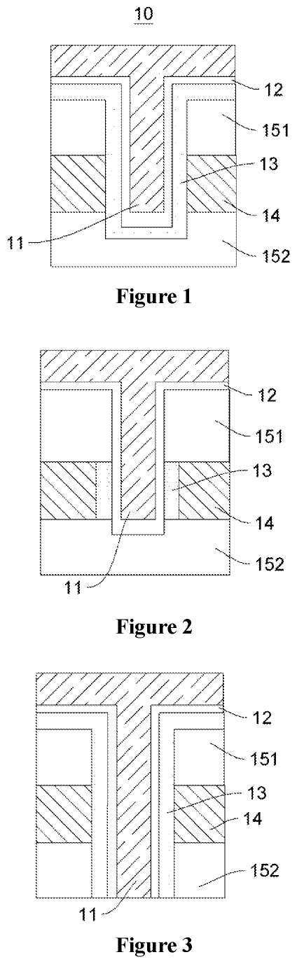

Referring to FIG. 1, a transistor device 10 is provided in an embodiment of the present disclosure, the transistor device 10 comprising a gate 11, a gate insulating layer 12, a semiconductor channel 13, a first source drain 151, and a second source drain 152.

In some implementations, the gate insulating layer 12 is arranged around the side of the gate 11. It is understood that the gate insulating layer 12 can be attached to the surface of the gate 11. That is, the surface of the gate 11 is wrapped by the gate insulating layer 12. There may be other thin film layer structure between the gate 11 and the gate insulating layer 12, which is not limited thereto. The semiconductor channel 13 is arranged around the side of the gate insulating layer 12 away from the gate 11. For example, the side of the gate insulating layer 12 away from the gate 11 can be wrapped by the semiconductor channel 13. The first source drain 151 is arranged around the side of the gate insulating layer 12 away from the gate 11 and is disposed at a first end of the gate 11. The second source drain 152 is arranged around the side of the gate insulating layer 12 away from the gate 11 and is disposed at a second end of the gate 11.

Through the above structural design, a CAA (Channel-All-Around) structure is formed between the semiconductor channel 13 and the gate 11. That is, the semiconductor channel 13 is surrounded on the outside of the gate 11, which can effectively increase the area of the semiconductor channel 13, increase the number of carriers in the semiconductor channel 13, and improve the efficiency of the current conduction. At the same time, since the semiconductor channel 13 is completely surrounded on the outside of the gate 11, the area of the semiconductor channel 13 corresponding to the gate 11 is effectively increased, thereby improving the control ability of the gate 11 on the semiconductor channel 13. This design structure increases the control area of the gate 11 on the semiconductor channel 13 and the area of the semiconductor channel 13 in a limited volume and can achieve relatively small miniaturization.

In this embodiment, the contact between the semiconductor channel 13 and the first source drain 151 and the second source drain 152 can be achieved in at least two ways as follows.

One optional implementation is that the first source drain 151 and the second source drain 152 are both arranged around the side of the gate insulating layer 12 away from the gate 11. The first source drain 151 is connected to a first end of the semiconductor channel 13, and the second source drain 152 is connected to a second end of the semiconductor channel 13. That is, the first source drain 151 and the second source drain 152 are connected at the ends of the semiconductor channel 13, as shown in FIG. 2.

Another optional implementation is that the first source drain 151 can be arranged on the surface of the semiconductor channel 13 away from the gate 11 and located at a first end of the semiconductor channel 13, and the second source drain 152 is arranged on the surface of the semiconductor channel 13 away from the gate 11 and located at a second end of the semiconductor channel 13, as shown in FIG. 3. This implementation can achieve a relatively large contact area between the source drain and the semiconductor channel 13. It is beneficial to the conduction efficiency of carriers. In addition, in the manufacturing process, the patterning mask process can be reduced, and the semiconductor channel 13 does not need to be etched.

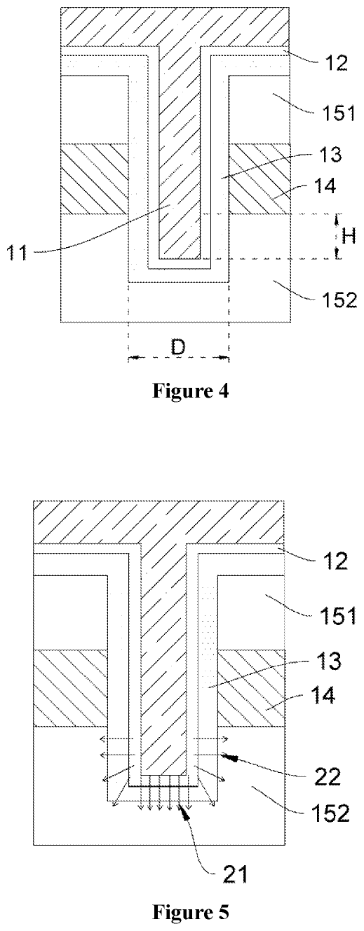

In some implementations, the second end of the semiconductor channel 13 is wrapped by the second source drain 152. That is, the gate insulating layer 12 at the second end of the semiconductor channel 13 is wrapped by the second source drain 152, and the second end of the semiconductor channel 13 and the second end of the gate 11 extend into the second source drain 152, as shown in FIG. 4. The gate 11 and the semiconductor channel 13 extend into the second source drain 152, and the contact area between the semiconductor channel 13 and the second source drain 152 will be larger.

Referring to FIG. 5, since the gate 11 also extends deeply into the second source drain 152, the second end of the gate 11 can form an electric field (referred to in this embodiment as a first electric field 21 for ease of later expression) in a direction away from the first end of the gate 11, and an electric field (referred to in this embodiment as a second electric field 22 for ease of later expression) can be formed in a direction to the sides of the semiconductor channel 13, which are the locations where the semiconductor channel 13 is connected to the source drain. Thus, the structure of the gate 11 and the semiconductor channel 13 extending into the second source drain 152 may further enhance the control ability of the gate 11 on the contact position of the semiconductor channel 13 in which the semiconductor channel 13 is in contact with the second source drain 152, so as to enhance the performance of the entire device and avoid the generation of a leakage current.

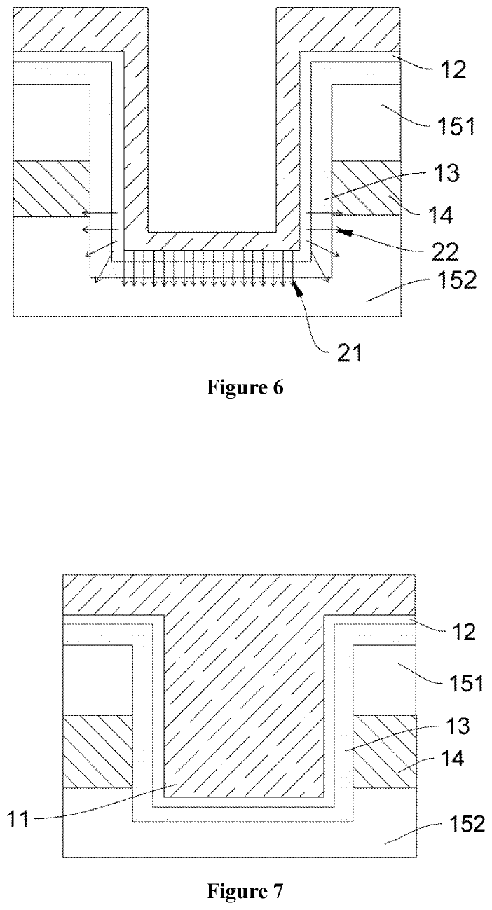

In some implementations, in order to ensure the control ability of the second end of the gate 11 on the semiconductor channel 13, the length of the gate 11 extending into the second source drain 152 can be set to be not less than 10 nm, so that there is a sufficient width of the second electric field 22 to ensure a better control performance on the semiconductor channel 13 contacted by the second source drain 152. At this time, the outer diameter of the end of the semiconductor channel 13 extending into the second source drain 152 can be controlled to be less than 50 nm to achieve device miniaturization. Of course, in some other implementations, the outer diameter of the second end of the semiconductor channel 13 can also be set larger, as shown in FIGS. 6 and 7. Thus, the first electric field 21 generated by the gate 11 is sufficient to cover the second source drain 152, which can also achieve effective control of the gate 11. At this time, the control ability of the gate 11 on the second end of the semiconductor channel is mainly determined by the first electric field 21, and the length of the gate 11 extending into the second source drain 152 is not limited to be less than 10 nm.

In some implementations, if a semiconductor channel 13 with a larger outer diameter is used, it may be difficult to reduce the size of the device. Therefore, in order to ensure that the second end of the gate 11 has a good control performance on the second end of the semiconductor channel 13, the outer diameter of the end of the semiconductor channel 13 that extends into the second source drain 152 and the length of the gate 11 that extends into the second source drain 152 can be controlled to satisfy a relationship: H≥0.5×(120 nm−D), where His the length of the gate 11 extending into the second source drain 152, and D is the outer diameter of the end of the semiconductor channel 13 extending into the second source drain 152. At this time, it is possible to control that D≤100 nm. Thus, the balance between the first electric field 21 and the second electric field 22 is achieved, which ensures the control performance of the gate 11 on the second end of the semiconductor channel 13, and is conducive to the further miniaturization and reduction of the device, as shown in FIG. 4. In addition, when the semiconductor channel 13 extends into the second source drain 152 and does not make a penetration, both the end surface and side surface of the end of the semiconductor channel 13 close to the second source drain 152 can form good contact with the second source drain 152, effectively reducing the contact resistance. In addition, when the diameter of the second end of the semiconductor channel 13 is designed to be larger, the contact between the semiconductor channel 13 and the second source drain 152 can be further increased, reducing the contact resistance.

In some implementations, the second source drain 152 is arranged around a surface of the semiconductor channel 13 away from the gate 11 and located at a second end of the semiconductor channel 13. This structure can facilitate etching the second source drain 152 to make a penetration during the manufacturing process, as shown in FIG. 3. Thus, the semiconductor channel 13, the gate insulating layer 12, and the gate 11 can be deposited within a hole, without the need for controlling the etching thickness of the second source drain 152.

In some implementations, the transistor device 10 may further include an electrode insulating layer, which is arranged around on a surface of the semiconductor channel 13 away from the gate 11 and is located between the first source drain 151 and the second source drain 152. The electrode insulating layer is used to isolate the first source drain 151 from the second source drain 152.

In some implementations, the transistor device 10 may further include a substrate, which is arranged on the side of the second source drain 152 away from the first source drain 151. The gate 11 can be arranged perpendicular to the substrate, so that a single transistor device 10 will occupy less area of the substrate, which is conducive to large-scale arrays and reduces the volume of the final product. It should be noted that “perpendicular” in this example refers to relative perpendicular or approximately perpendicular, rather than perpendicular in an absolute sense.

In some implementations, the substrate can use commonly used substrate materials, such as Si, SiO₂, SiC, etc., or even other flexible substrate materials, without limitation. The gate 11 can be made of ITO, IZO, TiN, etc., having good conductivity. It can also be made of metals or other highly conductive oxides that are favorable for growth by the ALD (Atomic Layer Deposition) process. The gate insulating layer 12 can be implemented with materials such as HfO, HfAIO, Al₂O₃, etc. Of course, the gate insulating layer 12 can also be made by combining multiple layers of different material films. The semiconductor channel 13 can be implemented with IGZO (Indium Gallium Zinc Oxide), and can also be made of derivative of IZTO (Indium Zinc Tin Oxide), IGZTO (Indium Gallium Zinc Tin Oxide) or the like with low leakage current and high mobility. The first source drain 151 and the second source drain 152 can be formed with TiN, W, Mo or the like, which may have better work functions for IGZO materials and better oxidation resistance properties.

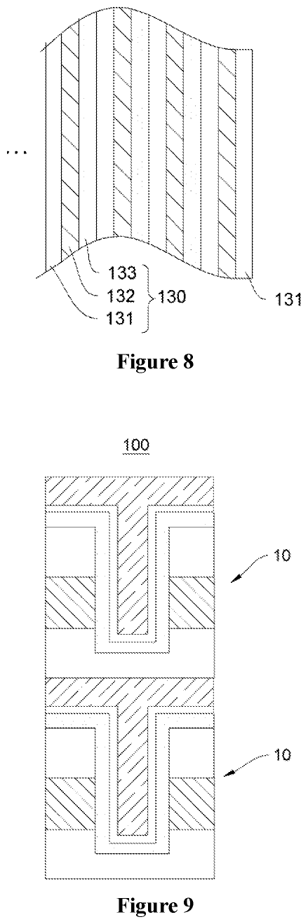

Referring to FIG. 8, the semiconductor channel 13 can be implemented with IGZO material. The semiconductor channel 13 includes a multi-layer thin film structure. The multi-layer thin film structure includes an indium oxide thin film layer 131, a gallium oxide thin film layer, and a zinc oxide thin film layer. Specifically, the multi-layer thin film structure can be formed by alternately stacking the indium oxide thin film layer 131, the gallium oxide thin film layer 132, and the zinc oxide thin film layer 133. The order of the alternating layers is not limited. The semiconductor channel 13 with a high proportion of indium can reach a larger on-state current at the same gate voltage, but the threshold voltage of the device is more negative. That is, the threshold voltage of the device is less than 0 V and is more distant from 0 V. The transistor threshold voltage of the semiconductor channel 13 with a low proportion of indium is more positive. That is, the threshold voltage of the device is greater than 0 V, or less than 0 V but closer to 0 V, but the device on-state current will be less. It is noted that depending on the requirements for the expected performance of the device, the reference that is used to judge whether it is close to positive or negative may vary. For example, −1 V may be taken as a reference, with greater than −1 V being close to positive and less than −1 V being close to negative. Thus, the ratio of each element of indium, gallium, and zinc can be accurately controlled during fabrication by the layered structure design in this embodiment, thereby enabling adjusting and balancing of the turn-off control ability of the semiconductor channel 13 and the mobility of the semiconductor channel 13.

In some implementations, the multi-layer thin film structure includes multiple unit structure layers 130 stacked sequentially. Each unit structure layer 130 includes an indium oxide thin film layer 131, a gallium oxide thin film layer 132, and a zinc oxide thin film layer 133. With this structure, cyclic stacking of the indium oxide thin film layer 131, the gallium oxide thin film layer 132, and the zinc oxide thin film layer 133 is achieved, which effectively improves carrier uniformity within the semiconductor channel 13, ensuring better mobility.

In some implementations, the unit structure layer 130 is sequentially stacked from a direction away from the gate 11 to a direction closer to the gate 11 by an indium oxide thin film layer 131, a gallium oxide thin film layer 132, and a zinc oxide thin film layer 133. It may also be stacked by a zinc oxide thin film layer 133, an indium oxide thin film layer 131, and a gallium oxide thin film layer 132. It may also be stacked by a gallium oxide thin film layer 132, an indium oxide thin film layer 131, and a zinc oxide thin film layer 133, or by a gallium oxide thin film layer 132, a zinc oxide thin film layer 133, and an indium oxide thin film layer 131. Such a stacked structure may ensure that the indium oxide thin film layer 131 and the gallium oxide thin film layer 132 are adjacent to each other, thereby effectively suppressing formation of oxygen vacancies and improving device control ability.

In some implementations, the proportion of indium oxide material in the unit structure layer 130 is 3/5 to 3/4, which can achieve greater on-state current at the same gate voltage condition of the transistor device 10. Optionally, the same ratio of the gallium oxide material as that of zinc oxide material in the unit structure layer 130 may be provided, which guarantees better turn-off performance of the gate 11 to the semiconductor channel 13 while guaranteeing that a large on-state current is reached, achieving a balance between high current and easy turn-off of the semiconductor channel 13. That is, in some possible implementations, the ratio of InOₓ:GaOₓ:ZnOₓ may be ranged from 3:1:1 to 6:1:1, e.g., 5:1:1.

Further, in this embodiment, the thickness of each of the indium oxide thin film layer 131, the gallium oxide thin film layer 132, and the zinc oxide thin film layer 133 is less than 1 Angstrom. In this way, even if the compounds of different layers are alternately deposited, the finally formed multi-element semiconductor thin film is not seen as a layered structure and can still be equivalently considered as a complete mixture of these several elements, guaranteeing the other properties of the IGZO material.

In some optional implementations, the semiconductor channel 13 further includes an outer thin film layer. The outer thin film layer is disposed on the surface of the multi-layer thin film structure closest to the gate 11. The material of the outer thin film layer is indium oxide. That is, an additional layer of indium oxide may be deposited after the last unit structure layer 130 is deposited, resulting in better interface characteristics and improved sub-threshold characteristics and operating current of the device. For example, if the material of the thin film of the unit structure layer 130 closest to the gate 11 is ZnOₓ, an additional layer of InOₓ is provided on the ZnOₓ to obtain better interface properties, as shown in FIG. 8.

In some implementations, the thickness of the semiconductor channel 13 is 3 nm to 5 nm, thereby ensuring better mobility of the semiconductor channel 13, while also facilitating microscopic and high-density large-scale arrays of the entire transistor device 10.

It should also be noted that a 2T0C device structure can be conveniently formed with a small footprint since the gate 11 of the transistor device 10 in this embodiment penetrates upward and the second source drain 152 is located below, as shown in FIG. 9. The gate 11 of one transistor device is connected with the second source drain 152 of another transistor device.

In summary, according to one or more embodiments of the present disclosure, there is provided a transistor device in which the surface of a gate is wrapped by a gate insulating layer, a surface of the gate insulating layer away from the gate is wrapped by a semiconductor channel, a first source drain is arranged around the side of the gate insulating layer away from the gate and is located at a first end of the gate, and a second source drain is arranged on the side of the gate insulating layer away from the gate and is located at a second end of the gate. The resulting transistor device structure forms a semiconductor channel-all-around gate, which increases the area of the semiconductor channel corresponding to the gate, effectively enhances the control ability of the gate on the semiconductor channel, and facilitates further miniaturization of the size of the device. At the same time, the semiconductor channel can have a relatively large area, increasing the number of carriers and improving the performance.

Based on the same inventive concept, in another embodiment of the present disclosure, there is also provided a memory including a transistor device as described in any one of the preceding embodiments.

It is to be noted that the present embodiment provides a memory which employs the transistor device in the preceding embodiment, and therefore the memory has beneficial effects which can be described with reference to the preceding embodiment and will not be repeated in the present embodiment. In addition, the transistor device and the specific process implementation when each structure in the memory is fabricated may be made using existing process technology and is not limited in this embodiment.

In the above description, the technical details such as the composition and etching of each layer are not described in detail. However, a person skilled in the art should understand that layers, regions, etc. of a desired shape can be formed by various technical means. In addition, in order to form the same structure, the person skilled in the art may also devise a method which is not exactly the same as the method described above. Furthermore, although the embodiments are described separately above, this does not mean that the measures in the various embodiments cannot be used advantageously in combination.

Although preferred embodiments of the present disclosure have been described, those skilled in the art may make additional changes and modifications to these embodiments once the basic inventive concepts are known. Therefore, the appended claims are intended to be construed to include the preferred embodiments as well as all changes and modifications that fall within the scope of the present disclosure.

Obviously, those skilled in the art can make various changes and variations to the present disclosure without departing from the spirit and scope of the present disclosure. Thus, to the extent that such modifications and variations of the present disclosure fall within the scope of the present claims and their technical equivalents, the present disclosure is intended to encompass those changes and variations as well.

1. A transistor device comprising:
a gate;
a gate insulating layer arranged around a side of the gate;
a semiconductor channel arranged around a side of the gate insulating layer away from the gate;
a first source drain arranged around the side of the gate insulating layer away from the gate and located at a first end of the gate; and
a second source drain arranged on the side of the gate insulating layer away from the gate and located at a second end of the gate.

2. The transistor device according to claim 1, wherein the first source drain and the second source drain are both arranged around a surface of the semiconductor channel away from the gate.

3. The transistor device according to claim 1, wherein the first source drain and the second source drain are both arranged around a surface of the gate insulating layer away from the gate, the first source drain is connected to a first end of the semiconductor channel, and the second source drain is connected to a second end of the semiconductor channel.

4. The transistor device according to claim 1, wherein a second end of the semiconductor channel is wrapped by the second source drain.

5. The transistor device according to claim 1, wherein a length of the gate extending into the second source drain is not less than 10 nm.

6. The transistor device according to claim 1, wherein an outer diameter of an end of the semiconductor channel extending into the second source drain is less than 50 nm.

7. The transistor device according to claim 1, wherein an outer diameter of an end of the semiconductor channel extending into the second source drain and a length of the gate extending into the second source drain satisfy a relationship: H≥0.5×(120 nm−D), where H is the length of the gate extending into the second source drain, and D is the outer diameter of the end of the semiconductor channel extending into the second source drain.

8. The transistor device according to claim 1, wherein the second source drain is arranged around a surface of the semiconductor channel away from the gate and is located at a second end of the semiconductor channel.

9. The transistor device according to claim 1, further comprising an electrode insulating layer arranged around a surface of the semiconductor channel away from the gate and located between the first source drain and the second source drain, wherein the electrode insulating layer is used to isolate the first source drain from the second source drain.

10. A memory comprising the transistor device according to claim 1.
